(19) United States
(12) Patent Application Publication
(10) Pub. No.: US 2025/0089205 A1
(43) Pub. Date: Mar. 13, 2025

(54) ROBOTIC VEHICLE FOR DELIVERING ITEMS

(71) Applicant: Direct Cursus Technology L.L.C, Dubai (AE)

(72) Inventors: Sergey BADANOV, Moscow (RU); Grigory PUGACHEV, Korolev (RU)

(21) Appl. No.: 18/630,483

(22) Filed: Apr. 9, 2024

(30) Foreign Application Priority Data
Sep. 12, 2023 (RU) 2023123620

(51) Int. Cl. H05K 7/20; B62D 63/04

(52) U.S. Cl. CPC H05K 7/20272; B62D 63/04

(57) ABSTRACT

A robotic vehicle for delivering items including a computer processor, a casing for housing the computer processor, a first coupling feature disposed on the casing, a housing disposed in a body of the robotic vehicle and configured to receive the casing, and a second coupling feature complimentary to the first coupling feature, disposed on the housing. The second coupling feature is configured to removably couple the first coupling feature and the second coupling feature configured to guide and position the casing via the first coupling feature in response to insertion of the casing into the housing.

### CROSS-REFERENCE

The present application claims priority to Russian Patent Application No. 2023123620, entitled “Robotic Vehicle for Delivering Items”, filed Sep. 12, 2023, the entirety of which is incorporated herein by reference.

### FIELD OF TECHNOLOGY

The present technology relates to a robotic vehicle for delivering items to a user, more specifically a coupling system for insertion of a computer processor.

### BACKGROUND

Autonomous robotic vehicles are vehicles that are able to autonomously navigate through private and/or public spaces. A computer processor, housed within the robotic vehicle, performs a number of tasks during use such as receiving signals from a system of sensors which detect location and/or surrounds and controlling the velocity and direction of the robotic vehicle based on said signals. Delivery robots, for example, are autonomous robotic vehicles configured to navigate streets for the delivery of items to a customer. Delivery robots include a container for receiving items for delivery, sensors positioned on an exterior of the delivery robot to provide information about the surrounding(s) during use, and a computer system for processing information from the sensors.

During operation, the components of the computer processor generate heat. Without an effective cooling system, the generated heat is unable to dissipate, resulting in damage to the components of the computer processor and potentially impacting the proper functioning of the robotic vehicle. To repair and maintain proper functioning of the robotic vehicle, the computer processor is accessed, and components are restored and/or replaced. However, the computer processor is not always easily accessible. Specifically, disconnecting and connecting the computer processor can be difficult and cumbersome.

Certain prior art approaches have been proposed to tackle the above-identified technical problem.

U.S. Pat. No. 11,001,443 B1, issued on May 11, 2021, assigned to Amazon Technologies, Inc., and entitled “DRAINAGE SYSTEM FOR A DELIVERY AUTONOMOUS GROUND VEHICLE”, discloses a delivery autonomous ground vehicle includes several drainage features to keep water away from the package to be delivered and sensitive components.

United States Patent Application Publication No.: 2021/070339 A1, published on Mar. 11, 2021, assigned to John Bradford King, and entitled “VEHICLE SYSTEMS AND METHODS”, discloses a vehicle system includes a chassis, a plurality of wheels coupled to the chassis and supporting the chassis for rolling on a surface, and a riding platform coupled to the chassis.

Chinese Utility Model No.: 214875236 U, issued on Nov. 26, 2021, assigned to Suzhou HYC Technology Co., Ltd., and entitled “INTELLIGENT MOBILE DEVICE”, discloses an intelligent mobile device, comprising a mobile base.

United States Patent Application Publication No.: 2021/197387 A1, published on Jul. 1, 2021, assigned to LG Electronics, Inc., and entitled “SELF-DRIVING ROBOT AND METHOD OF OPERATING THE SAME”, discloses a self-driving robot comprising: a loading box including at least one loading space; a communication circuit configured to transmit or receive a signal; an information collection device configured to detect a surrounding environment; a driving device configured to implement movement of the self-driving robot; and a processor configured to control the loading box, the communication circuit, and the information collection device.

### SUMMARY

It is an object of the present technology to ameliorate at least some of the inconveniences of the prior art.

In a broad aspect of the present technology, there is provided a robotic vehicle for delivering items including a computer processor, a casing for housing the computer processor, a first coupling feature disposed on the casing, a housing disposed in a body of the robotic vehicle and configured to receive the casing, and a second coupling feature complimentary to the first coupling feature and disposed on the housing. The second coupling feature is configured to be removably coupled to the first coupling feature and the second coupling feature is configured to guide and position the casing via the first coupling feature during insertion of the casing into the housing.

In some embodiments, the casing includes a cooling pathway for cooling the computer processor, and the first coupling feature includes a pathway outlet fluidly communicating with the cooling pathway for providing a coolant to the cooling pathway.

In some embodiments, the cooling pathway surrounds the computer processor and extends a length of the casing.

In some embodiments, the housing includes an outlet, the outlet fluidly communicating with an outer pathway of the body of the robotic vehicle for supplying the coolant, and the outlet fluidly communicating with the pathway outlet for supplying the coolant to the cooling pathway.

In some embodiments, the outlet of the housing and the pathway outlet of the first coupling feature are aligned upon coupling of the first coupling feature and the second coupling feature.

In some embodiments, the first coupling feature includes a first body portion and a second body portion with an intermediate body portion therebetween. The first body portion having the pathway outlet disposed therein, the intermediate body portion defining a chamber fluidly communicating with the pathway outlet, and the second body portion having an opening disposed therein, the opening fluidly communicating with the chamber of the intermediate body portion and the cooling pathway of the casing.

In some embodiments, the cooling pathway includes a first channel and a second channel, and the opening of the second body portion includes a first opening fluidly communicating with the first channel and a second opening fluidly communicating with the second channel.

In some embodiments, the first body portion, the second body portion, and the intermediate body portion are formed as a single, unitary piece.

In some embodiments, the first coupling feature includes a groove, and the second coupling feature includes a track being geometrically complimentary to the groove such that the track guides the insertion of the casing into the housing by interfacing with the groove of the first coupling member.

In some embodiments, the first coupling feature includes a first body portion and a second body portion with an intermediate body portion therebetween. The groove extends from an outer surface of the first body portion to an inner surface of the second body portion.

In some embodiments, the groove includes a tapered portion defining an outer wall of the intermediate body portion.

In some embodiments, the first body portion, the second body portion, and the intermediate body portion are formed as a single, unitary piece.

In some embodiments, the groove is continuous, forming a u-shaped groove and the track is continuous forming a u-shaped track.

In some embodiments, the first coupling feature is configured to be slideably inserted into the second coupling feature.

In some embodiments, the casing includes two first coupling features, and each of the two first coupling features are disposed on an outer surface of a side wall of the casing.

In some embodiments, the housing includes two second coupling features, each of the two second coupling features are disposed on a side wall of the housing.

In some embodiments, each of the two first coupling features are on opposing side walls of the casing and each of the two second coupling features are on the inner surface of opposing side walls of the housing.

In some embodiments, the second coupling feature is mounted to an inner surface of the housing.

In some embodiments, the housing is positioned in a front panel of the body of the robotic vehicle.

In some embodiments, the first coupling feature and the second coupling removably couple to one another for quick connect of the casing and the housing.

### BRIEF DESCRIPTION OF THE DRAWINGS

These and other features, aspects and advantages of the present technology will become better understood with regard to the following description, appended claims and accompanying drawings where:

FIG. 1 depicts a perspective view taken from a rear, right side of a robotic vehicle with a lid in a closed position, in accordance with some embodiments of the present technology;

FIG. 2 depicts a perspective view taken from a rear, right side of the robotic vehicle of FIG. 1 with a lid in an opened position, in accordance with some embodiments of the present technology;

FIG. 3 depicts a perspective view taken from a front right side of the robotic vehicle of FIG. 1, in accordance with some embodiments of the present technology;

FIG. 4 depicts a top plan view of a cooling system of the robotic vehicle of FIG. 1, in accordance with some embodiments of the present technology;

FIG. 5 depicts a perspective view of a first coupling feature of the robotic vehicle of FIG. 1, in accordance with some embodiments of the present technology;

FIG. 6 depicts a perspective view of a second coupling feature of the robotic vehicle of FIG. 1, in accordance with some embodiments of the present technology;

FIG. 7 depicts a front plan view of the first coupling feature of FIG. 5 and the second coupling feature of FIG. 6 with the first coupling feature interacting with the second coupling feature, in accordance with some embodiments of the present technology;

FIG. 8a depicts a front plan view of the first coupling feature of FIG. 5, in accordance with some embodiments of the present technology;

FIG. 8b depicts a right plan view of the first coupling feature of FIG. 5, in accordance with some embodiments of the present technology;

FIG. 8c depicts a rear plan view of the first coupling feature of FIG. 5, in accordance with some embodiments of the present technology;

FIG. 9 depicts a perspective view of half of the cooling system and the coupling system of the robotic vehicle of FIG. 1, according to some embodiments of the present technology;

FIG. 10a depicts a front view of an insertion position of the coupling system of FIG. 7, according to some embodiments of the present technology;

FIG. 10b depicts a front view of an intermediate position of the cooling system of FIG. 7, according to some embodiments of the present technology;

FIG. 10c depicts a front view of an alignment position of the cooling system of FIG. 7, according to some embodiments of the present technology; and

FIG. 11 depicts a perspective view of the cooling system and the coupling system of the robotic vehicle of FIG. 1, according to some embodiments of the present technology.

### DETAILED DESCRIPTION

Various representative implementations of the disclosed technology will be described more fully hereinafter with reference to the accompanying drawings. The present technology may, however, be implemented in many different forms and should not be construed as limited to the representative implementations set forth herein. In the drawings, the sizes and relative sizes of layers and regions may be exaggerated for clarity. Like numerals refer to like elements throughout.

The examples and conditional language recited herein are principally intended to aid the reader in understanding the principles of the present technology and not to limit its scope to such specifically recited examples and conditions. It will be appreciated that those skilled in the art may devise various arrangements which, although not explicitly described or shown herein, nonetheless embody the principles of the present technology and are included within its spirit and scope.

Furthermore, as an aid to understanding, the following description may describe relatively simplified implementations of the present technology. As persons skilled in the art would understand, various implementations of the present technology may be of a greater complexity.

In some cases, what are believed to be helpful examples of modifications to the present technology may also be set forth. This is done merely as an aid to understanding, and, again, not to define the scope or set forth the bounds of the present technology. These modifications are not an exhaustive list, and a person skilled in the art may make other modifications while nonetheless remaining within the scope of the present technology. Further, where no examples of modifications have been set forth, it should not be interpreted that no modifications are possible and/or that what is described is the sole manner of implementing that element of the present technology.

It will be understood that, although the terms first, second, third, etc. may be used herein to describe various elements, these elements should not be limited by these terms. These terms are used to distinguish one element from another. Thus, a first element discussed below could be termed a second element without departing from the teachings of the present disclosure. As used herein, the term “and/or” includes any and all combinations of one or more of the associated listed items.

It will be understood that when an element is referred to as being “connected” or “coupled” to another element, it can be directly connected or coupled to the other element or intervening elements may be present. By contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is only intended to describe particular representative implementations and is not intended to be limiting of the present technology. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The functions of the various elements shown in the figures, including any functional block labeled as a “processor,” may be provided through the use of dedicated hardware as well as hardware capable of executing software. When provided by a processor, the functions may be provided by a single dedicated processor, by a single shared processor, or by a plurality of individual processors, some of which may be shared. In some implementations of the present technology, the processor may be a general-purpose processor, such as a central processing unit (CPU) or a processor dedicated to a specific purpose, such as a digital signal processor (DSP). Moreover, explicit use of the term a “processor” should not be construed to refer exclusively to hardware capable of executing software, and may implicitly include, without limitation, an application-specific integrated circuit (ASIC), a field-programmable gate array (FPGA), a read-only memory (ROM) for storing software, a random-access memory (RAM), and non-volatile storage. Other hardware, conventional and/or custom, may also be included.

All statements herein reciting principles, aspects, and implementations of the present technology, as well as specific examples thereof, are intended to encompass both structural and functional equivalents thereof, whether they are currently known or developed in the future.

With these fundamentals in place, we will now consider some non-limiting examples to illustrate various implementations of aspects of the present disclosure.

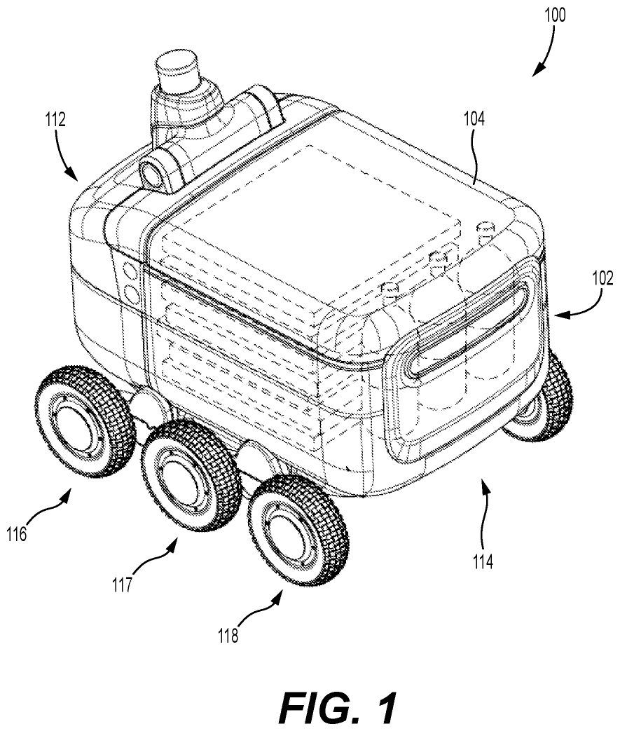

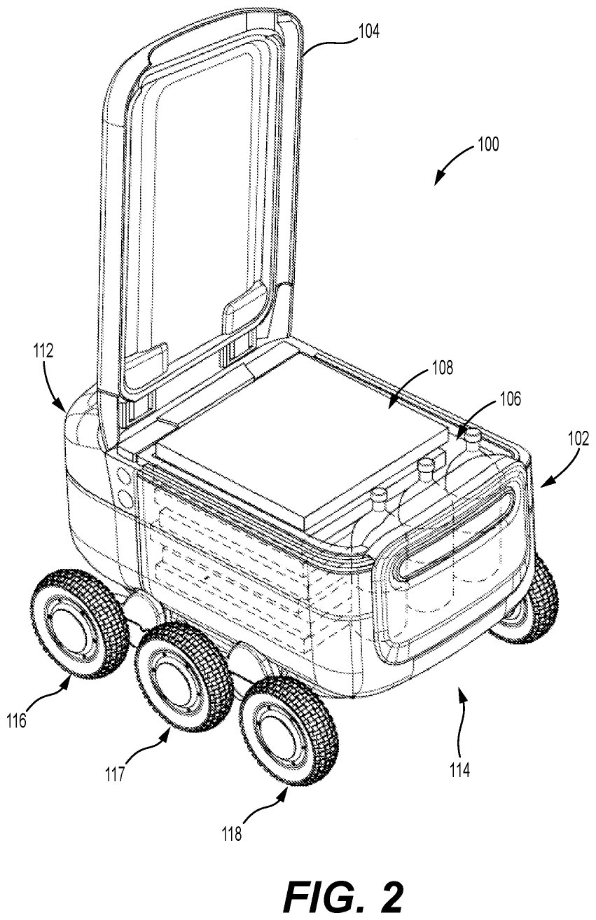

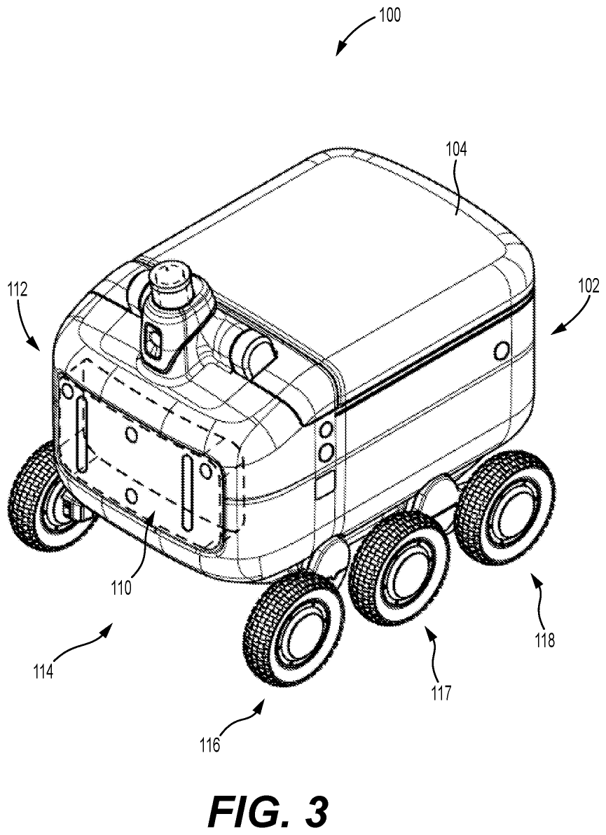

FIGS. 1 to 3 depict representations of a robotic vehicle 100 of the present technology. The robotic vehicle 100 includes a body 102 and a lid 104. Other configurations for different applications are also possible. The robotic vehicle 100 shown can be particularly used for the transfer of deliveries (such as mail, groceries, parcels, packages, flowers, medical equipment, and/or purchases). As depicted, the lid 104 is hingedly connected to the body 102 such that the lid 104 may be placed in a closed position (FIGS. 1 and 3) and an opened position (FIG. 2). It is appreciated that the lid 104 may have alternative configurations without departing from the scope of the present technology. When the lid 104 is in an opened position, access to the interior storage space 106 is provided for placing and/or removing items 108. The items 108 may be, for example, edible items, drinkable items, and/or non-consumable items.

A chassis 114 is arranged at the bottom of the robotic vehicle 100. In certain non-limiting embodiments of the present technology, three sets or pairs of wheels are provided-that is, wheels 116, wheels 117, and wheels 118. The robotic vehicle 100 also comprises illumination/signaling elements that are used for providing visual information to person(s) in the surroundings of the robotic vehicle 100. It is contemplated that a variety of systems and components of the robotic vehicle 100 may be attached to the chassis 114, such as, but not limited to: a suspension system, a battery, exterior panels, electronic components, and a body frame. In some implementations, the chassis 114 may be fabricated from aluminum. In other implementations, both the body 102 and the chassis 114 may be fabricated from a fiberglass material.

The robotic vehicle 100 may be a fully autonomous vehicle that may, in use, travel independently from any human decision, or a partially autonomous vehicle, in which a human operator can selectively remotely control some aspects of the robotic vehicle's operation, while other aspects are automated or where the human operator controls the operations under certain conditions (such as when the robotic vehicle 100 is stuck and cannot determine in an autonomous regime how to move forward). As one non-limiting example, the robotic vehicle 100 may operate autonomously unless or until it encounters an unexpected or unusual situation that it is unable to handle autonomously, at which time a remote human operator could be contacted. It should be noted that specific parameters of the robotic vehicle 100 are not limiting, these specific parameters including for example: manufacturer, model, year of manufacture, vehicle weight, vehicle dimensions, vehicle weight distribution, vehicle surface area, vehicle height, motor type, tire type (if tires are used), power system, or other characteristics or parameters of a vehicle. The robotic vehicle 100 could be any robotic vehicle, for delivery applications, warehouse applications, or the like.

The robotic vehicle 100 further includes a computer processor 110 housed within a casing 120. In some non-limiting embodiments of the present technology, the casing 120 is positionable within the body 102 of the robotic vehicle 100. As depicted in FIG. 3, in some non-limiting embodiments of the present technology, the casing 120 is configured to be removably inserted into the body 102, allowing the casing 120 (and thus, the computer processor 110) to be connected and disconnected for maintenance and/or repair of the computer processor 110. Specifically, in certain non-limiting embodiments of the present technology, the casing 120 is received by a housing 122 disposed in the body 102 of the robotic vehicle 100. For example, the housing 122 may be disposed in a front portion 112 to enable easy access to the casing 120 and computer processor 110 during maintenance of the robotic vehicle. However, it is contemplated that, in other non-limiting embodiments of the present technology, the computer processor 110 may be housed in another portion of the body 102 of the robotic vehicle 100.

In at least some non-limiting implementations of the present technology, the computer processor 110 is communicatively coupled to control systems of the robotic vehicle 100. The computer processor 110 could be arranged and configured to control different operation systems of the robotic vehicle 100, including but not limited to: motor control, steering systems, and signaling and illumination systems.

According to the non-limiting embodiments of the present technology, the implementation of the computer processor 110 is not particularly limited. For example, the computer processor 110 could be implemented as a vehicle motor control unit, a vehicle CPU, a computer processor built into the robotic vehicle 100, a plug-in control module, and the like.

In certain implementations, the computer processor 110 is part of an on-board computer system. In some embodiments of the present technology, the computer system may be at least partially housed within the casing 120. The computer system may include one or more processors, the storage device, and the memory. In other words, the computer system includes hardware and/or software and/or firmware, or a combination thereof, for processing data and performing a variety of actions in response to the processed data. For example, the computer processor 110 may receive data from one or more sensors and/or servers, process the received data, and trigger movement of the robotic vehicle 100 based on the processed data. A variety of sensors and systems may be used by the computer processor 110 for gathering information about surroundings of the robotic vehicle 100. The robotic vehicle 100 is equipped with a plurality of sensors (not numbered). It should be noted that different sensor systems may be used for gathering different types of data regarding the surroundings of the robotic vehicle 100. It is contemplated that a plurality of different sensor systems may be used in combination by the robotic vehicle 100. It is appreciated, in some embodiments of the present technology, the other electronic components of the computer system may generate heat during operation of the robotic vehicle 100. For example, in certain embodiments, the computer system may include a storage device, such as a solid-state drive or a hard drive, which generates heat during use. In some embodiments, the storage device is at least partially housed within the casing 120.

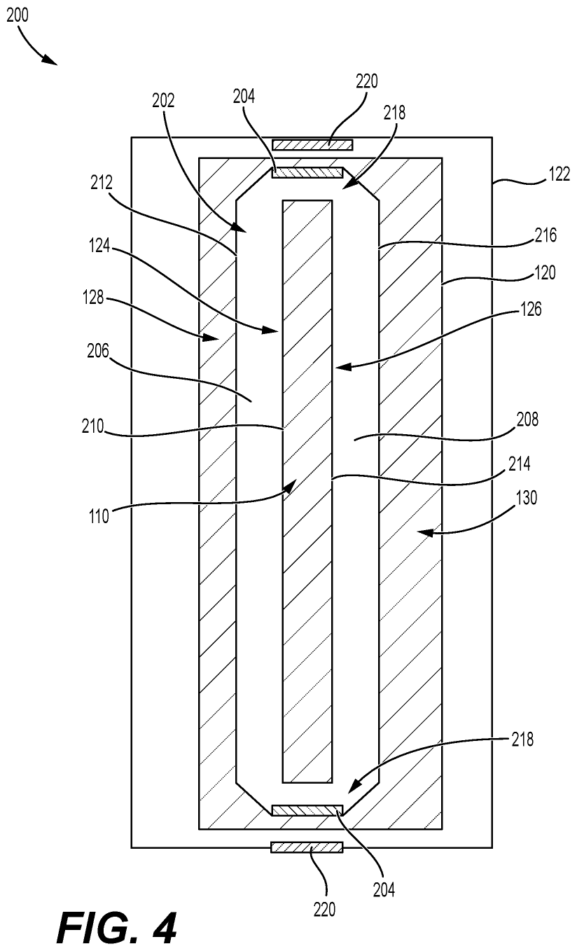

As the computer processor 110 controls the various operating systems of the robotic vehicle 100, heat is generated by the computer processor 110. With reference to FIG. 4, according to certain non-limiting embodiments of the present technology, the robotic vehicle 100 includes a cooling system 200 to avoid overheating and mitigate risk of damage to the computer processor 110.

Broadly, the cooling system 200 includes a cooling pathway 202 for cooling the computer processor 110 and a pathway outlet 204 fluidly communicating with the cooling pathway 202 for providing a coolant to the cooling pathway 202. In certain non-limiting embodiments of the present technology, the cooling pathway 202 is formed within the casing 120 and surrounds the computer processor 110.

In some non-limiting embodiments, the cooling pathway 202 is formed of two channels 206, 208 in fluid communication with each other. The first channel 206 is positioned along a first surface 124 of the computer processor 110. In some non-limiting embodiments, one sidewall 210 of the first channel 206 is defined by the first surface 124 of the computer processor 110 and the opposing sidewall 212 of the first channel 206 is defined by a first lateral wall 128 of the casing 120. Similarly, the second channel 208 is positioned along a second surface 126 of the computer processor 110. One sidewall 214 of the second channel 208 is defined by the second surface 126 of the computer processor 110 and the opposing sidewall 216 is defined by a second lateral wall 130 of the casing 120. In other non-limiting embodiments, the first and second channels 206, 208 may extend along the first and second surfaces 124, 126, respectively. In certain non-limiting embodiments, each of the first and second channels 206, 208 covers the entire respective surfaces 124, 126 of the computer processor 110. In other non-limiting embodiments of the present technology, each of the first and second channels 206, 208 may be in a different configuration. For example, the first and second channels 206, 208 may be in a serpentine configuration across the respective surfaces 124, 126. In further non-limiting embodiments of the present technology, the cooling system 200 may include a single channel along one of the surfaces of the computer processor 110. In other non-limiting embodiments of the present technology, the cooling system 200 may include more than two channels where each of the respective surfaces 124, 126 have a plurality of channels distributed across them.

As depicted in FIG. 4, in certain non-limiting embodiments of the present technology, the cooling system 200 includes two pathway outlets 204 fluidly communicating with the cooling pathway 202 for delivering the coolant. Specifically, each of the two pathway outlets 204 are in fluid communication with each of the two channels 206, 208 of the cooling pathway 202. As seen in FIG. 4, each of the pathway outlets 204 are disposed on opposing sides of the casing 120. However, alternative positioning of the pathway outlets 204 are considered, without departing from the scope of the present technology.

The cooling system 200 further includes two chambers 218 disposed at opposing ends of the casing 120 which fluidly connect the two channels 206, 208 with the pathway outlets 204. Additionally, the chambers 218 fluidly connect the two channels 206, 208 with one another. It is appreciated, in other non-limiting embodiments of the present technology, that other configurations of the chambers 218 may be used. In further alternative non-limiting embodiments, the chamber 218 may be omitted.

According to certain non-limiting embodiments of the present technology, the cooling system 200 further includes an outlet 220 disposed in the housing 122 of the robotic vehicle 100. As seen in FIG. 4, in some non-limiting embodiments of the present technology, the cooling system 200 includes two outlets 220 disposed on opposing ends of the housing 122. Each outlet 220 aligns with a respective pathway outlet 204 such that one outlet 220 is in fluid communication with one pathway outlet 204 for providing the coolant to the cooling pathway 202. Specifically, each outlet 220 is aligned with a respective pathway outlet 204 when the casing 120 is inserted in (received by) the housing 122, such that there is fluid communication between each outlet 220 and the cooling pathway 202 (via the respective pathway outlet 204). In certain non-limiting embodiments of the present technology, the coolant is any substance which allows for the transfer of heat from the computer processor 110 to the coolant, for example the coolant may be air or a dielectric fluid.

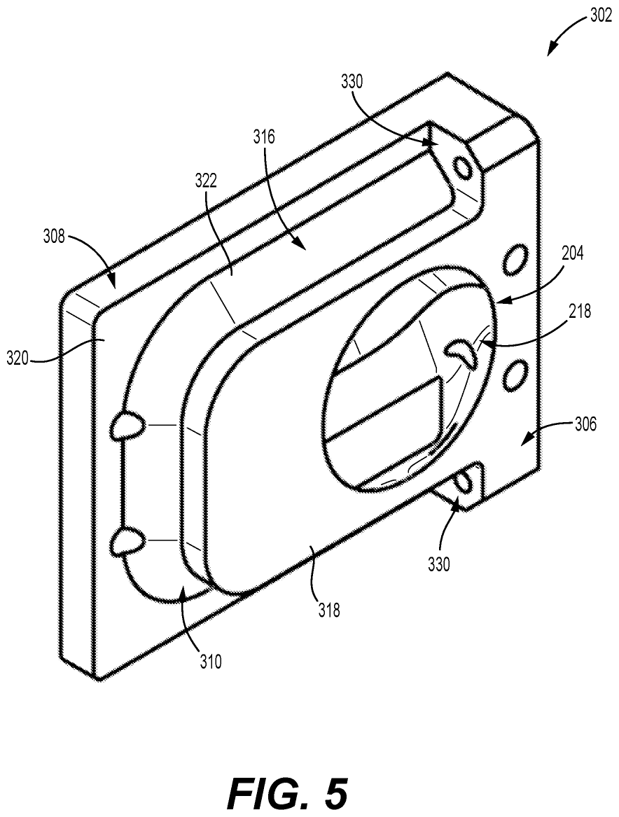

FIGS. 5 to 10, depict non-limiting embodiments of a coupling system 300 of the robotic vehicle 100. According to some non-limiting embodiments of the present technology, the coupling system 300 is associated with the casing 120 and the housing 122 to enable proper positioning and alignment of the casing 120 when inserted into the housing 122. The coupling system 300 further provides a quick connect and disconnect of the casing 120 from the housing 122 during maintenance and repair of the computer processor 110.

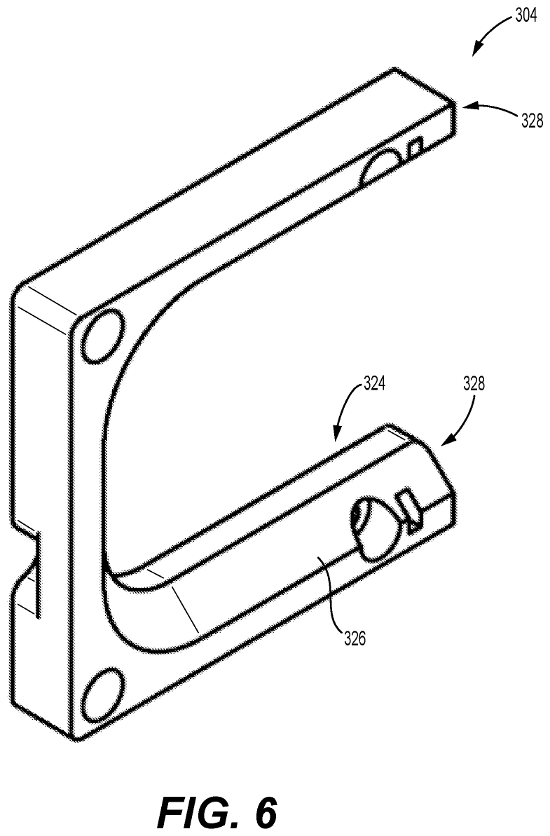

With reference to FIGS. 5 and 6, in some non-limiting embodiments of the present technology, the coupling system 300 includes a first coupling feature 302 (seen in FIG. 5) and a second coupling feature 304 (seen in FIG. 6). The first coupling feature 302 and the second coupling feature 304 are complimentary to one another to enable the first coupling feature 302 and the second coupling feature 304 to removably and selectively couple to one another for quick connect and/or disconnect of the casing 120 and the housing 122. In certain embodiments, the first coupling feature 302 has a slideable relationship with the second coupling feature 304. In other words, the first coupling feature 302 is slideably inserted into the second coupling feature 304. In some embodiments, so-coupling the first coupling feature 302 with the second coupling feature 304 may allow for single-handed coupling of the casing 120 and the housing 122.

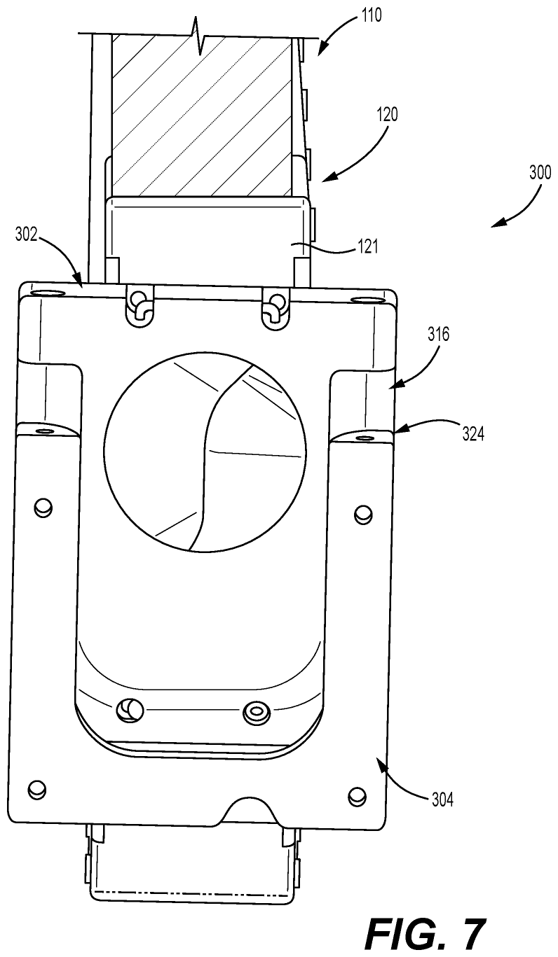

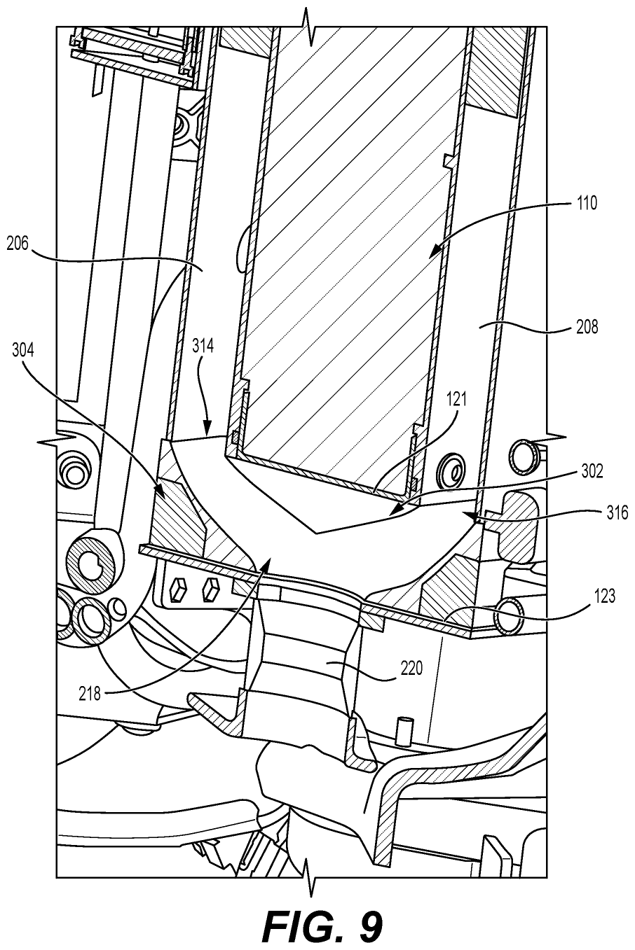

As shown in FIGS. 7 and 9, in certain non-limiting embodiments of the present technology, the first coupling feature 302 is configured to be disposed on the casing 120. As seen in FIG. 7, in some non-limiting embodiments, the first coupling feature 302 is removably mounted onto a portion of an outer surface of one of the sidewalls 121 of the casing 120. For example, the first coupling feature 302 may be mounted to the outer surface by fasteners, such as bolts or screws. In other non-limiting embodiments, the first coupling feature 302 may be permanently secured to the portion of the outer surface of one of the side walls 121 of the casing 120, such as welded, glued, etc. In other non-limiting embodiments, the first coupling feature 302 defines at least a portion of one of the sidewalls 121 of the casing 120.

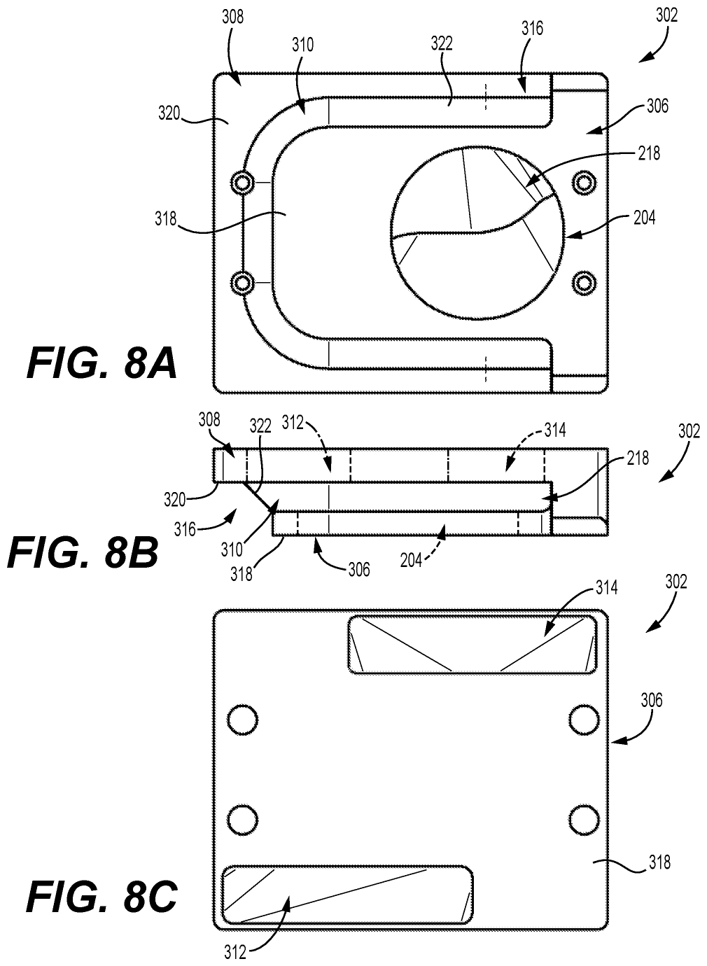

FIGS. 5 and 8a-8c depict the first coupling feature 302, according to some non-limiting embodiments of the present technology. In some non-limiting embodiments, the first coupling feature 302 includes a body. The body of the first coupling feature 302 includes a first body portion 306, a second body portion 308, and an intermediate body portion 310 therebetween. In certain non-limiting embodiments, the first body portion 306, second body portion 308, and intermediate body portion 310 are formed as a single, unitary piece. It can be said that the first body portion 306, the second body portion 308 and, the intermediate body portion 310 may be integrally formed. In other non-limiting embodiments, the first body portion 306, second body portion 308, and intermediate body portion 310 are formed of a plurality of pieces secured together. It can be said that the first body portion 306, the second body portion 308 and, the intermediate body portion 310 may be assembled to form the feature 302.

In certain non-limiting embodiments of the present technology, the cooling system 200 is associated with the coupling system 300. That is, the coupling system 300 includes features of the cooling system 200.

In some non-limiting embodiments of the present technology, the first coupling feature 302 includes the pathway outlet 204 and the chamber 218. Specifically, the pathway outlet 204 is disposed in the first body portion 306 and the chamber 218 is defined by the intermediate body portion 310.

With reference to FIG. 8c, in some non-limiting embodiments of the present technology, the second body portion 308 includes openings to fluidly connect the chamber 218 with the first and second channels 206, 208 of the cooling system 200. Specifically, the second body portion 308 includes a first opening 312 fluidly connecting the first channel 206 with the chamber 218, and a second opening 314 fluidly connecting the second channel 206 with the chamber 218.

In some non-limiting embodiments of the present technology, the first coupling feature 302 includes a groove 316 complimentary to a corresponding portion of the second coupling feature 304 (which will be described in further detail below). The groove 316 is configured to engage and removably couple with the corresponding portion of the second coupling feature 304 for quick connect and disconnect between the first and second coupling features 302, 304 and/or to assist in positioning the first and second coupling features 302, 304 (and thereby the casing 120 and the housing 122).

The groove 316 extends along a portion of the first coupling feature 302. In certain non-limiting embodiments of the present technology, the body of the first coupling feature 302 forms the groove 316. The groove 316 may extend from an inner surface of the body towards an outer surface. In some instances, the groove 316 may extend the entire width of the body. That is, the groove 316 is defined by two walls. In other cases, the groove 316 may extend partially towards the opposing surface, such that the groove 316 is defined by three walls.

In certain non-limiting embodiments of the present technology, the groove 316 extends from the first body portion 306 to the second body portion 308. As seen in FIG. 8b, the groove 316 extends from an outer surface 318 of the first body portion 306 towards an inner surface 320 of the second body portion 308. In certain non-limiting embodiments, the groove 316 is positioned along a portion of an outer perimeter of the first coupling feature 302. For example, as seen in FIGS. 5 and 8a, the groove 316 is continuous, forming a u-shape. The groove 316 is positioned along three edges of the first coupling feature 302. Referring to FIG. 8b, in some non-limiting embodiments of the present technology, the groove 316 further includes a groove tapered portion 322 that defines an outer wall of the intermediate body portion 310. It is appreciated that other configurations of the groove 316 may be implemented without departing from the scope of the present technology. For example, in other non-limiting embodiments of the present technology, the groove 316 may be linear and extend along a single edge of the first coupling feature 302.

With reference to FIGS. 6 and 8, according to some non-limiting embodiments of the present technology, the second coupling feature 304 is configured to be disposed on the housing 122. Specifically, in some non-limiting embodiments, the second coupling feature 304 is disposed on a sidewall of the housing 122. In certain non-limiting embodiments of the present technology, the second coupling feature 304 is mounted onto a portion of an inner surface of one of the sidewalls 123 of the housing 122. In other non-limiting embodiments of the present technology, the second coupling feature 304 defines at least a portion of one of the sidewalls 123 of the housing 122.

According to certain non-limiting embodiments of the present technology, the second coupling feature 304 is configured to enable fluid communication between the outlet 220 and the pathway outlet 204. In some non-limiting embodiments, the second coupling feature 304 may be configured to avoid obstructing the outlet 220. In other non-limiting embodiments, the second coupling feature 304 may include an outlet opening which aligns with the outlet 220 of the housing 120 to allow for fluid communication when the first coupling feature 302 is inserted into the second coupling feature 304.

In some non-limiting embodiments of the present technology, the second coupling feature 304 includes a track 324. The track 324 is geometrically complimentary to the groove 316 of the first coupling feature 302. In some non-limiting embodiments, the entirety of the second coupling feature 304 is composed of the track 324. For example, as depicted in FIG. 6, the second coupling feature 304 is formed is a continuous, u-shaped track 324. The track 324 further includes a track tapered portion 326 (complimentary to the groove tapered portion 322). The u-shaped configuration of the track 324 (and thus the second coupling feature 304) avoids obstructing the outlet 220 of the housing 122, allowing fluid communication between the pathway outlet 204 and the outlet 220 when the first coupling feature 302 is inserted into the second coupling feature 304. It is appreciated that the track 324 may have different configurations without departing from the scope of the present technology.

The track 324 of the second coupling feature 304 interacts with the groove 316 of the first coupling feature 302 to guide the insertion of the first coupling feature 302 (and thereby the insertion of the casing 120 into the housing 122). The track 324 assists positioning of the first coupling feature 302 such that the casing 120 is properly inserted into the housing 122. In some non-limiting embodiments of the present technology, the proper positioning of the casing 120 within the housing 122 aligns the outlet 220 of the housing 122 with the pathway outlet 204 disposed on the first coupling feature 302.

It is appreciated that, in other non-limiting embodiments of the present technology, the first and second coupling features 302, 304 may removably engage one another in other types of mating configurations.

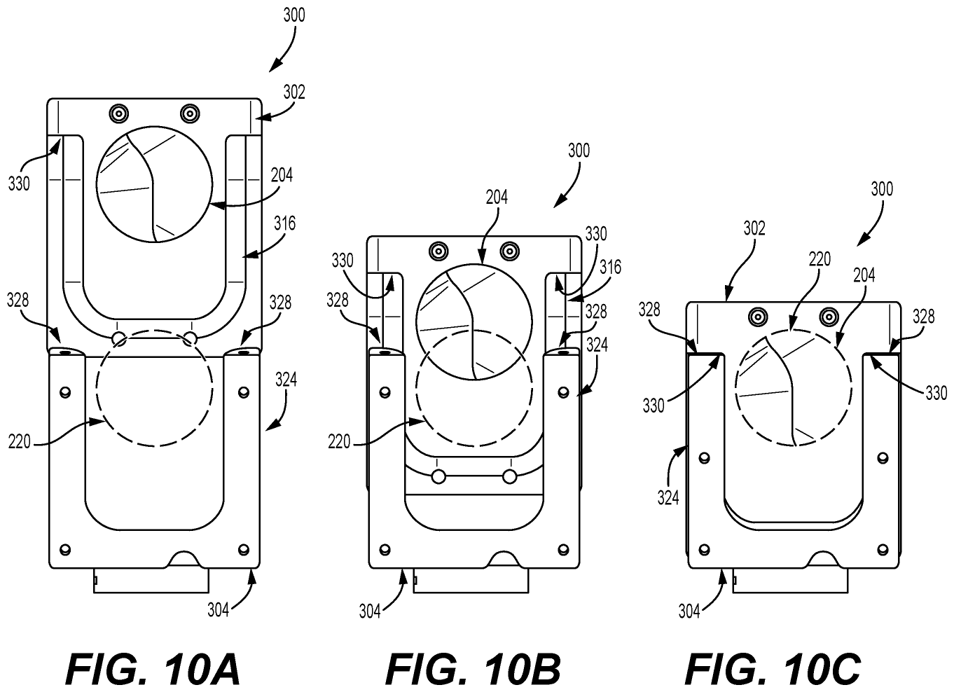

FIGS. 10a-10c, in some non-limiting embodiments of the present technology, depicts insertion of the first coupling feature 302 into the second coupling feature 304. Specifically, as seen in in FIG. 10a, the first coupling feature 302 is first positioned in an insertion position relative to the second coupling feature 304. That is, the first coupling feature 302 is positioned such that the groove 316 is aligned with the track 324 of the second coupling feature 304. FIG. 10b depicts an intermediate position as the first coupling feature 302 is advanced into the second coupling feature 304. In this position, the groove 316 and the track 324 engage one another such that the track 324 guides the insertion of the first coupling feature 302 along the groove 316. As shown in FIG. 10c, the first coupling feature 302 is advanced until reaching an alignment position where an abutment surface 328 of the track 324 contacts an abutment surface 330 of the groove 316, halting any further advancement and, in some non-limiting embodiments, aligning the outlet 220 with the pathway outlet 204.

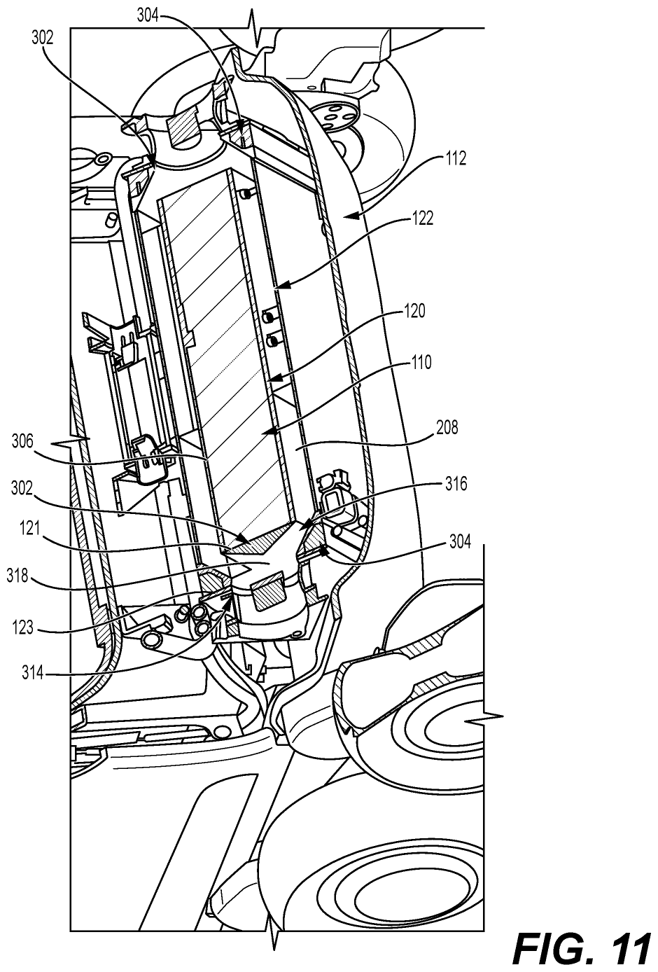

With reference to FIG. 11, in some non-limiting embodiments of the present technology, the coupling system 300 includes two first coupling features 302 and two, complimentary, second coupling features 304. The two first coupling features 302 are positioned on opposing sides of the casing 120. Similarly, the two second coupling features 304 are positioned on opposing sides of the housing 122. It is appreciated that, in other non-limiting embodiments of the present technology, the two first coupling features 302 do not need to be positioned on opposing sides of the casing 120 and, similarly, the two second coupling features 304 do not need to be positioned on opposing sides of the housing 122. For example, the two first and second coupling features 302, 304 may be disposed on adjacent sidewalls of the casing 120 and the housing 122, respectively. It is further appreciated that any number of the first and second coupling features 302, 304 may be implemented without departing from the scope of the present technology. For example, the coupling system 300 may include one first coupling feature 302 and one second coupling feature 304.

In alternative non-limiting embodiments of the present technology, it is appreciated that the cooling system 200 and the coupling system 300 do not need to be associated with one another and may be implemented independently without departing from the scope of the present technology. For example, the coupling system 300 may solely include the first coupling feature 302 having the groove 316 and the second coupling feature 304 having the complimentary track 324, while the casing 120 and the housing 122 include the features of the cooling system 200.

It should be expressly understood that not all technical effects mentioned herein need to be enjoyed in each and every implementation of the present technology.

Modifications and improvements to the above-described implementations of the present technology may become apparent to those skilled in the art. The foregoing description is intended to be exemplary rather than limiting. The scope of the present technology is therefore intended to be limited solely by the scope of the appended claims.

1. A robotic vehicle for delivering items comprising:
a computer processor;
a casing for housing the computer processor;
a first coupling feature disposed on the casing;
a housing disposed in a body of the robotic vehicle and configured to receive the casing; and
a second coupling feature complimentary to the first coupling feature disposed on the housing,
the second coupling feature configured to removably couple to the first coupling feature; and
the second coupling feature configured to guide and position the casing via the first coupling feature in response to insertion of the casing into the housing.

2. The robotic vehicle of claim 1, wherein:
the casing comprises a cooling pathway for cooling the computer processor; and
the first coupling feature comprises a pathway outlet fluidly communicating with the cooling pathway for providing a coolant to the cooling pathway.

3. The robotic vehicle of claim 2, wherein the cooling pathway surrounds the computer processor and extends a length of the casing.

4. The robotic vehicle of claim 2, wherein:
the housing comprises an outlet;
the outlet fluidly communicating with an outer pathway of the body of the robotic vehicle for supplying the coolant; and
the outlet fluidly communicating with the pathway outlet for supplying the coolant to the cooling pathway.

5. The robotic vehicle of claim 4, wherein the outlet of the housing and the pathway outlet of the first coupling feature are aligned upon coupling of the first coupling feature and the second coupling feature.

6. The robotic vehicle of claim 2, wherein:
the first coupling feature comprises a first body portion and a second body portion with an intermediate body portion therebetween;
the first body portion having the pathway outlet disposed therein;
the intermediate body portion defining a chamber fluidly communicating with the pathway outlet; and
the second body portion having an opening disposed therein, the opening fluidly communicating with the chamber of the intermediate body portion and the cooling pathway of the casing.

7. The robotic vehicle of claim 6, wherein:
the cooling pathway comprises a first channel and a second channel; and
the opening of the second body portion comprises:
a first opening fluidly communicating with the first channel; and
a second opening fluidly communicating with the second channel.

8. The robotic vehicle of claim 6, wherein the first body portion, the second body portion, and the intermediate body portion are formed as a single, unitary piece.

9. The robotic vehicle of claim 1, wherein:
the first coupling feature comprises a groove; and
the second coupling feature comprises a track being geometrically complimentary to the groove such that the track guides the insertion of the casing into the housing by interfacing with the groove of the first coupling member.

10. The robotic vehicle of claim 9, wherein:
the first coupling feature comprises a first body portion and a second body portion with an intermediate body portion therebetween; and
the groove extends from an outer surface of the first body portion to an inner surface of the second body portion.

11. The robotic vehicle of claim 10, wherein the groove comprises a tapered portion defining an outer wall of the intermediate body portion.

12. The robotic vehicle of claim 10, wherein the first body portion, the second body portion, and the intermediate body portion are formed as a single, unitary piece.

13. The robotic vehicle of claim 9, wherein the groove is continuous, forming a u-shaped groove and the track is continuous, forming a u-shaped track.

14. The robotic vehicle of claim 1, wherein the first coupling feature is configured to be slideably inserted into the second coupling feature.

15. The robotic vehicle of claim 1, wherein the casing comprises two first coupling features, and each of the two first coupling features are disposed on an outer surface of a side wall of the casing.

16. The robotic vehicle of claim 15, wherein the housing comprises two second coupling features, each of the two second coupling features disposed on a side wall of the housing.

17. The robotic vehicle of claim 16, wherein each of the two first coupling features are on opposing side walls of the casing and each of the two second coupling features are on the inner surface of opposing side walls of the housing.

18. The robotic vehicle of claim 1, wherein the second coupling feature is mounted to an inner surface of the housing.

19. The robotic vehicle of claim 1, wherein the housing is positioned in a front panel of the body of the robotic vehicle.

20. The robotic vehicle of claim 1, wherein the first coupling feature and the second coupling feature removably couple to one another for quick connect of the casing and the housing.
